(19) United States
(12) Patent Application Publication
(10) Pub. No.: US 2012/0282756 A1
(43) Pub. Date: Nov. 8, 2012

(54) Thin Film Filling Method

(76) Inventor: Lingkuan Meng, Beijing (CN)

(21) Appl. No.: 13/505,993

(22) PCT Filed: Jan. 18, 2012
(86) PCT No.: PCT/CN12/00092

§ 371 Date: May 3, 2012

(30) Foreign Application Priority Data
Mar. 23, 2011 (CN) 201110070705.7

(51) Int. Cl. H01L 21/762

(52) U.S. Cl. 438/435; 257/E21.546

(57) ABSTRACT

The present invention relates to a thin film filling method, including: feeding reactive gases including a silicon-containing gas, an oxygen-containing gas, an inert gas and a fluent gas into a reaction chamber; forming a first deposited thin film in the trench or gap through HDP CVD; feeding an etching gas and the fluent gas without feeding said silicon-containing gas and oxygen-containing gas, to sputter the surface of the first deposited thin film; feeding said silicon-containing gas and oxygen-containing gas without feeding said etching gas, so that a second deposited thin film is formed on the surface of the sputtered first deposited thin film; feeding said etching gas and fluent gas without feeding said silicon-containing gas and oxygen-containing gas, to sputtering the surface of said second deposited thin film; repeating the last two steps; feeding the silicon-containing gas and oxygen-containing gas without feeding the etching gas to form a plasmas of low pressure and high density, so that a third deposited thin film, which completely fills said trench or gap, is formed on the surface of the sputtered second deposited thin film.

### CROSS REFERENCE

This application is a National Stage Application of, and claims priority to, PCT Application No. PCT/CN2012/000092, filed on Jan. 18, 2012, entitled “A Thin Film Filling Method”, which claims priority to Chinese Application No. 201110070705.7 filed on Mar. 23, 2011. Both the PCT application and the Chinese application are incorporated herein by reference in their entireties.

### FIELD OF THE INVENTION

The present invention relates to the technical field of semiconductor integrated circuit manufacturing, in particular to a thin film filling method.

### BACKGROUND OF THE INVENTION

One of the persistent challenges faced in the development of semiconductor industry is parasitic effect resulted from increased density of circuit elements, which results in interconnection delay. Such delay is becoming a bottleneck affecting adversely devices. With technology progress, such adverse effect can be reduced by physical and electrical isolation of insulating material, for example, employing low-k material technique, or gap technique, etc. For gap isolation, as circuit densities increase, however, the widths of these gaps decrease, increasing their aspect ratios and making it progressively more difficult to fill the gaps without leaving voids. The formation of voids when the gap is not filled completely is undesirable because they may adversely affect operation of the completed device, resulting in current leakage or device malfunction.

Common techniques that are used to fill a gap are chemical-vapor deposition (“CVD”) techniques. In conventional thermal CVD processes, heat-induced chemical reactions take place to produce a desired film. Plasma-enhanced CVD (“PECVD”) techniques promote excitation and/or dissociation of the reactant gases by the application of radio-frequency (“RF”) energy, thereby creating plasma. The high reactivity of the species in the plasma reduces the energy required for a chemical reaction to take place, and thus lowers the temperature required for the chemical reaction. However, the AR of the gap increases when device dimension decrease continuously. As a result, PECVD cannot fill gaps with higher AR. In some methods that replace or improve PECVD, with respect to some examples of gaps having large AR values and narrow widths, a thin film is filled by the PECVD technique with a process sequence of depositing-etching-depositing, that is, a thick layer of thin film is deposited first, then etching a part thereof away and depositing material again. The gap can be re-opened by the etching step to from opening, and subsequently material can be filled in until the opening is closed. Voids generally are formed inside the filled gap. However, such improved PECVD technique cannot be used to fill gaps with large AR (>2:1) values, even with a sequence of deposition and etching steps.

At present, HDP CVD (High-Density Plasma Chemical Vapor Deposition) has been widely used to fill trenches with AR of 2:1 or larger and width of 0.3 μm or smaller encountered in, for example, shallow-trench-isolation (“STI”) structures, for technology nodes of 0.25 μm or smaller. With the generation of plasmas, deposition and sputtering occur simultaneously. Sputtering can effectively open trenches and slows deposition near openings, so that there are enough time to fill trenches from bottom before the openings are closed, just as conventional PECVD. HDP CVD has excellent gapfill characteristics due to the combination of sputtering and deposition.

FIG. 1 is a schematic diagram of filling a thin film into a trench or gap in a single step in the current HDP CVD semiconductor manufacturing technique. It can be seen that, voids and so on are possibly formed in a thin film filled into the trench or gap having a high AR value. This is because that in conventional HDP CVD, a problem encountered by sputtering is the angle-dependent effect of the bombarding material. The deposited thin film will be re-deposited on the other side of the trench or gap under the bombardment of ions. Too much are deposited on said side that the trench or gap can't be opened and consequently the trench or gap cannot be fully filled, with voids buried in.

If the thin film filled in the trench or gap contains voids, interconnect metal formed in the following processes is probably filled into said voids, thus paths of high leakage current will occur between elements, which result in device failure and reduced yield.

### SUMMARY OF THE INVENTION

In view of this, the present invention provides a thin film filling method, which can effectively realize void-free thin film filling of a trench or gap.

An embodiment of the present invention is implemented as follows:

A thin film filling method, comprising:

step A: feeding reactive gases including a silicon-containing gas, an oxygen-containing gas, an inert gas and a fluent gas into a reaction chamber where a semiconductor substrate with a trench or gap is placed;

step B: forming a plasmas of low pressure and high density from the reactive gases through HDP CVD to form a first deposited thin film in the trench or gap;

step C: feeding an etching gas and the fluent gas without feeding said silicon-containing gas and oxygen-containing gas, to sputter the surface of the first deposited thin film to prevent the trench or gap from being closed;

step D: feeding said silicon-containing gas and oxygen-containing gas without feeding said etching gas, to form a plasmas of low pressure and high density, so that a second deposited thin film is formed on the surface of the sputtered first deposited thin film;

step E: feeding said etching gas and fluent gas without feeding said silicon-containing gas and oxygen-containing gas, to sputtering the surface of said second deposited thin film to prevent the trench or gap from being closed;

repeating steps D˜E for N times and then proceeding to step F, wherein N is an integer greater than or equal to 1;

step F: feeding the silicon-containing gas and oxygen-containing gas without feeding the etching gas to form a plasmas of low pressure and high density, so that a third deposited thin film, which completely fills said trench or gap, is formed on the surface of the sputtered second deposited thin film.

Preferably, a Sputter/Deposition ratio for the formation of the second deposited thin film is greater than or equal to that for the formation of the first deposited thin film; and a Sputter/Deposition ratio for the formation of the third deposited thin film is greater than or equal to that for the formation of the second deposited thin film.

Preferably, the Sputter/Deposition ratios for the formation of the first deposited thin film and the second deposited thin film fall in a range of 0.05˜0.15.

Preferably, the Sputter/Deposition ratio for the formation of the third deposited thin film falls in a range of 0.15˜0.25.

Preferably, the first deposited thin film has a thickness of 30˜50% of the depth of the trench of gap.

Preferably, sputtering the surface of the first deposited thin film includes etching away the first depositing thin film by 5˜15% its thickness; and

sputtering the surface of the second deposited thin film includes etching away the second deposited thin film by 5˜15% its thickness.

Preferably, the second deposited thin film has a thickness of ⅔˜¾ of the depth of the trench or gap.

Preferably, the inert gas includes H₂ or a mixture of H₂ and He.

Preferably, the inert gas further includes Ar.

Preferably, the etching gas includes H₂.

Preferably, the etching gas further includes NF₃.

Preferably, step C and step E further include:

feeding a gas that can react with residual F atoms and/or free species in the thin film without feeding the etching gas and the fluent gas, so as to eliminate the residual F atoms and/or free species in the thin film.

Preferably, the gas that can react with residual F atoms and/or free species in the thin film includes H₂.

Preferably, the fluent gas includes H₂.

Preferably, the silicon-containing gas includes SiH₄.

Preferably, the oxygen-containing gas includes O₂.

Preferably, if the filled thin film is fluorosilicate glass, the reactive gases further include a fluorine-containing silicon-based gas; if the filled thin film is phosphorosilicate glass, the reactive gases further include a phosphoric gas; if the filled thin film is borosilicate glass, the reactive gases further include a boron-containing gas; if the filled thin film is boron-phosphorosilicate glass, the reactive gases further include a boron-containing gas and a phosphoric gas.

Compared to the prior art, the technical solution provided by the embodiments of the present invention has the following advantages and characteristics:

The present invention performs thin film deposition-thin film etching in a cyclic manner to fill a thin film into a trench or gap in a semiconductor substrate, and sputters the previously deposited thin film through etching to prevent the trench or gap from being closed and to achieve a better filling effect, finally realizes void-free thin film filling of the trench or gap.

### BRIEF DESCRIPTION OF THE DRAWINGS

In order to illustrate the technical solution in the embodiment of the present invention or in the prior art more clearly, a brief introduction will be given below for the drawings to be used in the embodiment. Obviously, the drawings in the following description are only some embodiments of the present invention, while those skilled in the art can obtain other drawings on the basis of these ones without using any inventive skills.

FIG. 1 is a schematic diagram of filling a trench or gap with a thin film by a single-step process in the conventional HDP CVD semiconductor manufacturing technique;

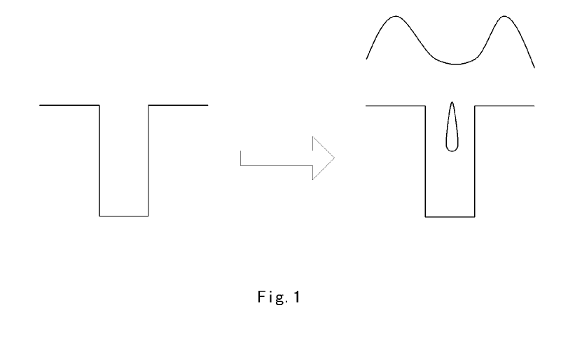

FIG. 2 is a flow chart of a thin film filling method provided by a embodiment of the present invention;

FIG. 3 is a flow chart of another thin film filling method provided by a embodiment of the present invention;

FIG. 4 is a schematic diagram of the respective phases of depositing a thin film in an STI gap, as provided by the embodiment of the present invention;

FIG. 5 is a flow chart corresponding to the process of filling a thin film in a STI structure as shown in FIG. 4;

FIG. 6 is a flow chart of another process of filling a thin film in a STI structure;

FIG. 7 is a schematic diagram of still another process of filling a thin film in a STI structure.

### DETAILED DESCRIPTION OF THE PREFERRED EMBODIMENTS

A clear and complete description will be given below for the technical solution in the embodiments of the present invention with reference to the drawings in the embodiments of the present invention.

The processing method of the present invention can be widely applied to various fields, and many appropriate materials can be used. The method will be described through specific embodiments. But, of course, the present invention is not limited to the specific embodiments, and the general substitutions well known to those skilled in the art should certainly fall within the protection scope of the present invention.

Moreover, the present invention is described in detail with reference to the schematic diagrams, and when expatiating the embodiments of the present invention, to facilitate the description, the sectional views showing device structures will be partially enlarged not according to the general proportion, but they should not be construed as limiting the invention; besides, during the actual manufacturing, the sizes in three dimensions, i.e. length, width and depth, should be included.

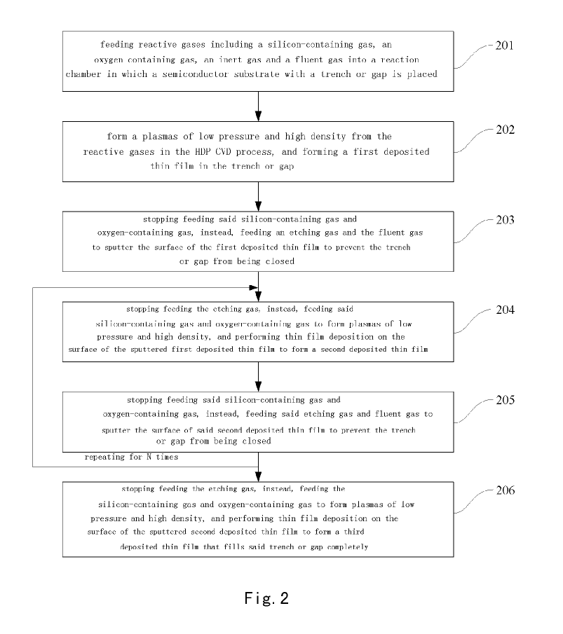

An embodiment of the present invention provides a thin film filling method to effectively carry out void-free thin film filling in a trench or gap, as shown in FIG. 2. The method embodiment includes the following steps:

step 201: feeding reactive gases including a silicon-containing gas, an oxygen-containing gas, an inert gas and a fluent gas into a reaction chamber in which a semiconductor substrate with a trench or gap is placed;

step 202: form a plasmas of low pressure and high density from the reactive gases in the HDP CVD process, and forming a first deposited thin film in the trench or gap;

step 203: stopping feeding said silicon-containing gas and oxygen-containing gas, instead, feeding an etching gas and the fluent gas to sputter the surface of the first deposited thin film to prevent the trench or gap from being closed;

step 204: stopping feeding the etching gas, instead, feeding said silicon-containing gas and oxygen-containing gas to form plasmas of low pressure and high density, and performing thin film deposition on the surface of the sputtered first deposited thin film to form a second deposited thin film;

step 205: stopping feeding said silicon-containing gas and oxygen-containing gas, instead, feeding said etching gas and fluent gas to sputter the surface of said second deposited thin film to prevent the trench or gap from being closed;

repeating steps 204˜205 for N times and then proceeding to step 206, wherein N is an integer greater than or equal to 1;

step 206: stopping feeding the etching gas, instead, feeding the silicon-containing gas and oxygen-containing gas to form plasmas of low pressure and high density, and performing thin film deposition on the surface of the sputtered second deposited thin film to form a third deposited thin film that fills said trench or gap completely.

In the present invention, thin films are deposited and etched alternatively to fill the trench or gap in the semiconductor substrate. During sputtering, the deposited thin film are etched back to prevent the trench or gap from closing. A better filling effect is achieved. Eventually, void-free thin films are filled in the trench or gap.

In the above embodiment, first, a pad oxide layer and a silicon nitride layer with certain thickness are deposited on a wafer as a mask during the following STI (Shallow Trench Isolation) gap etching The silicon nitride layer and silicon oxide layers are respectively patterned using photolithography process for the corresponding technical node, and a desired gap structure is dry etched. Then, a thermal oxide layer is grown on the surface of the gap structure. The corners of the gap are rounded by anneal, and then an HDP CVD filling process is performed.

A high density plasmas is formed at a lower pressure in HDP CVD, compared with in PECVD to provide active plasma species with a long mean free path. Consequently a significant number of constituents from the plasma can reach even the deepest portions of the gap, providing films with improved gapfill capabilities.

Specifically, a high-density plasma is used to fill the trench or gap in the HDP CVD, where two power systems are used, i.e. a source power system for generating the plasmas and a bias power system for sputtering and bombarding. The source power system provides energy to excite and maintain the plasmas at the high density. The bias power system provides energy to the ions in the plasmas to increase the speed at which the wafer is bombarded. The high-energy ions bombard the surface of the wafer to perform physical sputtering. In addition, by taking advantage of the unique way of simultaneous deposition and sputter in the HDP CVD, a thin film filling with a high AR value can be realized.

The most important application of the HDP CVD technique is gap filling, which is also the most prominent advantage thereof. It is crucial to select proper technological parameters to realize reliable void-fee gap filling. Generally, Sputter/Deposition ratio (S/D) is used as an index representing the filling ability of the HDP CVD technique. Here, the definition of S/D is: Sputter/Deposition=sputter rate/deposition rate=sputter rate/(net deposition rate+sputter rate).

The deposition rate refers to a deposition rate in a case where there is no sputtering etching; the net deposition rate is a deposition rate measured when deposition and sputtering are occurring simultaneously; the sputter rate is a sputter rate measured when there is no deposition silicon-based precursor in the reaction chamber and the pressure in the reaction chamber is adjusted to the deposition condition.

For void-free gapfill, it is desirable that the top of the gap remains opened for all depositing phases, so that species can enter and fill the gap from the bottom. Sputter/Deposition ratio which is an index representing gapfill capabilities of the HDP CVD technique need to be adjusted to improve the gapfill capabilities. All parameters that can notably affect the deposition rate or the etching rate will directly determine the gapfill capabilities of the insulating medium.

According to an embodiment of the present invention, void-free thin film filling is carried out using an HDP CVD system with a sequence of deposition-etching-deposition-etching-deposition steps. In order to achieve a better filling effect, the four steps before the final deposition step can be performed cyclically as required. In addition, the Sputter/Deposition ratio for the formation of the second deposited thin film should be greater than or equal to the Sputter/Deposition ratio for the formation of the first deposited thin film, so that the trench or gap can have a large enough opening; the Sputter/Deposition ratio for the formation of the third deposited thin film should be greater than or equal to the Sputter/Deposition ratio for the formation of the second deposited thin film so as to realize the final void-free thin film filling. First, the trench or gap is filled at a low Sputter/Deposition ratio with the first deposited thin film up to a thickness of approximately 30%˜50% of the depth of the trench or gap. Then the first deposited thin film is etched back by 5%-15% of its thickness. The same or slightly larger Sputter/Deposition ratio is used to form the second deposited thin film up to ⅔˜¾ of the depth of the trench or gap. The second deposited thin film is etched back by 5%-15% of its thickness. Finally, the remaining space in the gap or trench is filled with a higher Sputter/Deposition ratio to obtain the desired thin film thickness.

In an embodiment of the present invention, the reactive gases for depositing the silicon oxide thin film include: a silicon-containing gas (e.g. SiH₄), an oxidizing gas (e.g. O₂), an inert gas (e.g. He), and a fluent or dilute gas (e.g. H₂). Of course, during practical implementation, the reactive gases depend on the dopants contained in the oxide. For example, when preparing fluorosilicate glass (FSG), a silicon-based gas containing fluorine, i.e. SiF₄, needs to be added; when preparing phosphorosilicate glass (PSG) used as an ILD (Inter Layer Dielectric) layer, a phosphoric gas PH₃ needs to be added; when preparing borosilicate glass (BSG) used as an ILD layer, a boron-containing gas B₂H₆ needs to be added.

In advanced high aspect ratio gapfill, the fluent gas includes mainly H₂, and He with a high atomic weight may be added for sputtering and protecting the underlying substrate thin film. Most common gapfill can be achieved using pure He inert species without adding H₂ as dilute gas. However, material will be sputtered from the deposited thin film to the opposite side of the gap with higher aspect ratio to cause a re-deposition effect, since He produces stronger sputtering than H₂. H₂ is mainly used to realize void-free filling of the gap with a high aspect ratio. Because H₂ has a smaller atomic weight and a smaller sputtering effect on the deposited thin film, there is less amount of material is re-deposited from the thin film on the opposite side, so that the opening of the trench or gap will not be closed too soon.

The deposited thin film is etched back physically using H₂ alone as an etching gas or chemically using both H₂ and NF₃ as etching gases to keep the gap opened. The NF₃ plasmas may be generated either by in situ dissociation or by remote dissociation, the latter has a less damage to reaction chamber.

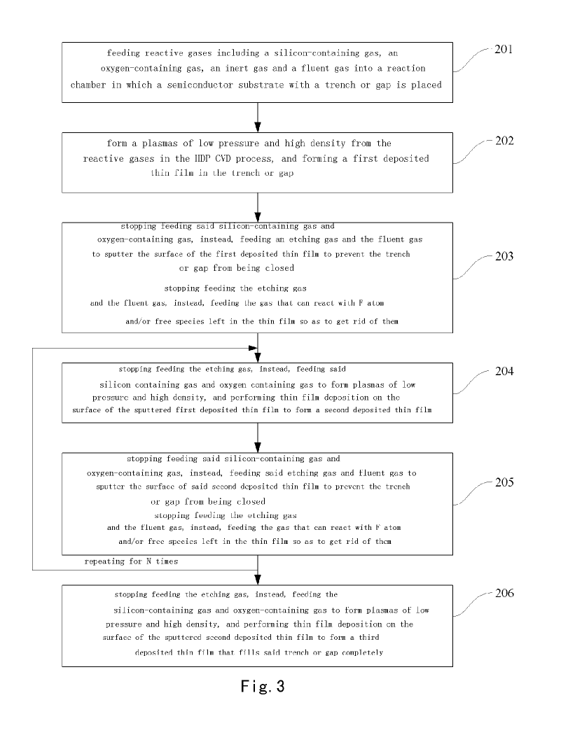

In some embodiments where NF₃ is used as an etching gas, F-containing atoms or free species will be left in the deposited thin film or in the chamber after a portion of the thin film has been etched away. This will affect adversely the thin film quality. In particular, during the deposition of an STI thin film, if a large amount of F is left, it will be accumulated in the filled thin film. The deposited thin film will be eroded due to the existence of F which is very active. The quality of the thin film and hence the electrical performance of the device will be affected adversely, causing an electrical isolation failure. In addition, during the deposition of the thin film, some particles left on the chamber will probably drop into the trench to cause trench defects, which result in the formation of voids. Such defects are potentially very harmful to the electrical performance. Furthermore, after CMP (Chemical Mechanical Polishing), said defects will leave scratches on the surface of the device, thereby affecting adversely the subsequent interconnection process. Thereby, a process for passivating the thin film is needed to get rid of F atom and free species left in the thin film, as shown in FIG. 3. For this, in the embodiment of the present invention, the following process are added in steps 203 and 205: stopping feeding the etching gas and the fluent gas, instead, feeding the gas that can react with F atom and/or free species left in the thin film so as to get rid of them. In said process, the flow of all gases is stopped, and then a certain amount of reactive gas that can react with F atom and/or free species, such as H₂ of 1000 sccm, is feed.

The embodiment of the present invention relates to the deposition of an oxide thin film using a high-density plasma technique so as to realize void-free gapfill. The technique of the present invention for depositing an oxide thin film has very good gapfill ability and can be used for filling such structures and layers as ILD, STI, PMD (Pre-Metal Dielectric) layer and IMD (Inter-Metal Dielectric).

The technical solution of the present invention will be described in detail below through specific embodiments.

### Embodiment 1

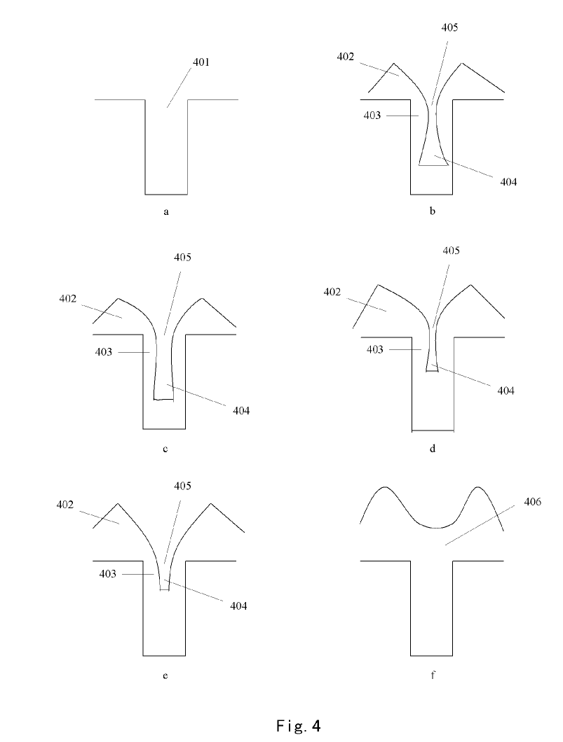

As shown in FIG. 4a, an STI structure 401 is formed on the surface of a substrate, wherein the pad oxide layer and nitride layer thin films grown in a furnace and the thin film oxide layer grown in the gap are omitted. After thermal processing and anneal, first deposition film may begin with the HDP CVD reaction chamber. For easy illustration, only one STI structure is shown as an example. The formation of the STI structure and the active region are well known and will not be described in detail herein. The semiconductor substrate may comprise any appropriate semiconductor substrate material, including, but not limited to, silicon, germanium, silicon germanium, SOI (Silicon On Insulator), silicon carbide, gallium arsenide or any III-V compound semiconductor.

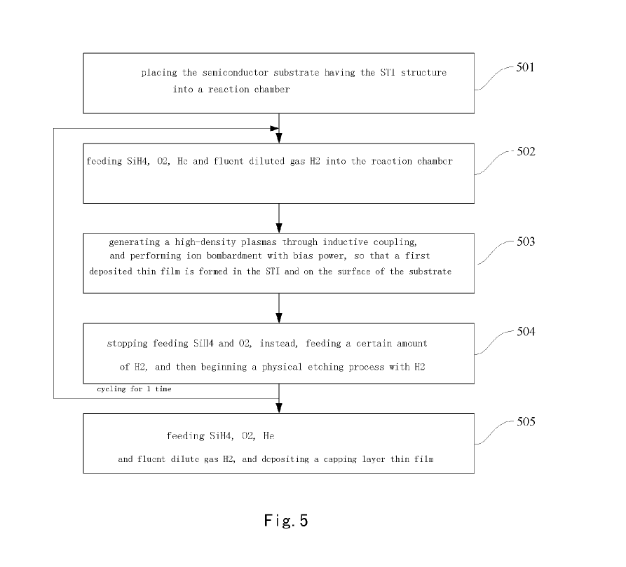

FIG. 5 shows a flow chart of filling a thin film into the STI structure as shown in FIG. 4a, which specifically includes the following steps:

step 501: placing the semiconductor substrate having the STI structure into a reaction chamber;

step 502: feeding SiH₄, O₂, He and fluent diluted gas H₂ into the reaction chamber;

step 503: generating a high-density plasmas through ICP, and performing ion bombardment with bias power, so that a first deposited thin film is formed in the STI and on the surface of the substrate;

step 504: stopping feeding SiH₄ and O₂, instead, feeding a certain amount of H₂, and then beginning a physical etching process with H₂.

In step 503, S/D is low to increase the deposition rate so that the thin film can grow from bottom of the gap without closing the opening.

Steps 502˜504 are repeated, and a second deposited thin film is formed on the surface of the first deposited thin film by deposition and etching The value of S/D for forming the second deposited thin film is equal to or slightly greater than that for the first, which may be in a range of 0.05˜0.15. And the flow of H₂ is higher than that for the formation of the first deposited thin film. For example, H₂/He is 400 sccm/300 sccm for the formation of the first deposited thin film, while H₂/He increases to 600 sccm/200 sccm when forming the second deposited thin film, thereby reducing the probability of lateral re-deposition.

The process proceeds to step 505, which includes feeding SiH₄, O₂, He and fluent dilute gas H₂, and depositing a capping layer thin film. In said step, S/D may be in a range of 0.15˜0.25 by adjusting the bias power. For example, a bias power of 6000-10000 W may be applied to a substrate wafer with a diameter of 300 mm. The flow of H₂ may be controlled as desired to maintain the opening unclosed, meanwhile material of the deposited thin film can be sputtered onto other portions thereof with He so as to improve the uniformity of the entire thin film.

FIGS. 4b-4f are schematic diagrams of respective stages of depositing a thin film in a gap of STI, corresponding to the flow chart of FIG. 5. FIG. 4b shows the deposited thin film formed in step 503. Because of the simultaneous deposition/sputter nature of HDP-CVD processes, a tip 402 is formed under the impact of sputtering ions and a thin film 403 is deposited on the side walls. Since the contact angle is large near the corners, the amount of the deposited thin film is the greatest near the corner, and consequently a gap 404 shaped like a key is formed. The upper end 405 indicates that the gap is close to disappearing. According to step 504, only He and H₂ are retained, and H₂ is adjusted to an appropriate flow. Opening 405 is formed by physical etching with H₂, as shown in FIG. 4c. Next, a second deposited thin film is formed on the upper surface of the substrate, and meanwhile the gap 404 and the upper end 405 become smaller, as shown in FIG. 4d. Then, 405 that is nearly closed is opened by physical etching with H2, as shown in FIG. 4e. Then, a capping layer thin film is formed to complete the filling of the thin film 406, as shown in FIG. 4f.

### Embodiment 2

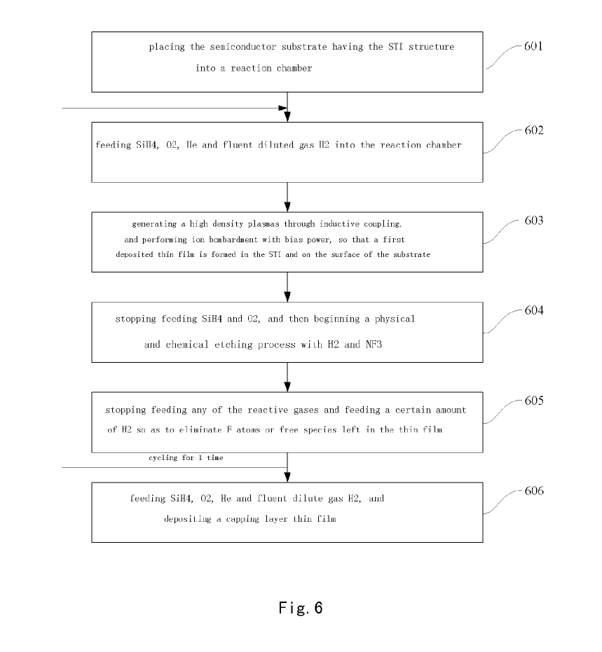

FIG. 6 shows another process flow of filling a thin film into a STI structure, which specifically includes the following steps:

step 601: placing the semiconductor substrate having the STI structure into a reaction chamber;

step 602: feeding SiH₄, O₂, He and fluent diluted gas H₂ into the reaction chamber;

step 603: generating a high-density plasmas through inductive coupling, and performing ion bombardment with bias power, so that a first deposited thin film is formed in the STI and on the surface of the substrate;

step 604: stopping feeding SiH₄ and O₂, and then beginning a physical and chemical etching process with H₂ and NF₃.

In step 603, S/D is low to increase the deposition rate so that the thin film can grow from bottom of the gap without closing the opening.

Unlike embodiment 1, the etching gases in said embodiment further include NF₃, and F-containing atoms or free species will be left in the deposited thin film or in the chamber after a portion of the thin film has been etched away. This will affect adversely the thin film quality. In order to get rid of F atoms or free species left in the thin film, a step is added in the embodiment of the present invention, which is:

step 605: stopping feeding any of the reactive gases and feeding a certain amount of H₂ so as to eliminate F atoms or free species left in the thin film.

Steps 602˜605 are repeated, and a second deposited thin film is formed on the surface of the first deposited thin film by deposition and etching The value of S/D for forming the second deposited thin film is equal to or slightly greater than that for the first, which may be in a range of 0.05˜0.15. And the flow of H₂ is higher than that for the formation of the first deposited thin film. For example, H₂/He is 400 sccm/300 sccm for the formation of the first deposited thin film, while H₂/He increases to 600 sccm/200 sccm when forming the second deposited thin film, thereby reducing the probability of lateral re-deposition.

The process proceeds to step 606, which includes feeding SiH₄, O₂, He and fluent dilute gas H₂, and depositing a capping layer thin film. In said step, S/D may be in a range of 0.15˜0.25 by adjusting the bias power. For example, a bias power of 6000˜10000 W may be applied to a substrate wafer with a diameter of 300 mm. The flow of H₂ may be controlled as desired to maintain the opening unclosed, meanwhile material of the deposited thin film can be sputtered onto other portions thereof with He so as to improve the uniformity of the entire thin film.

### Embodiment 3

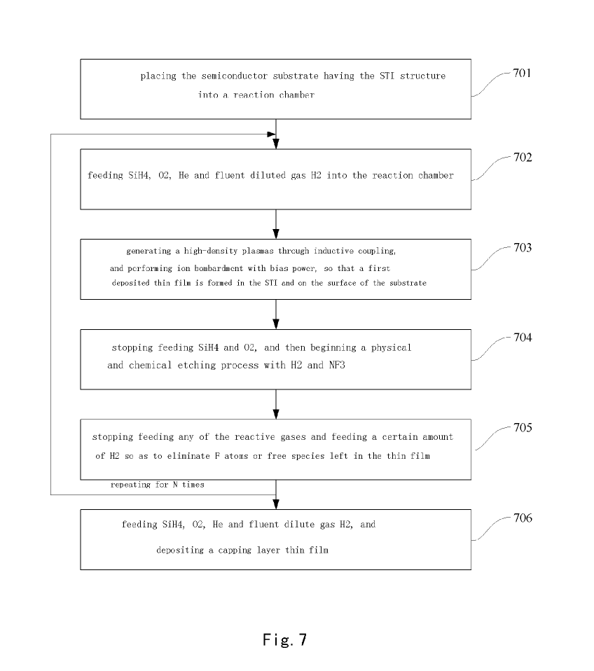

FIG. 7 shows another process flow of filling a thin film into a STI structure, which specifically includes the following steps:

step 701: placing the semiconductor substrate having the STI structure into a reaction chamber;

step 702: feeding SiH₄, O₂, He and fluent diluted gas H₂ into the reaction chamber;

step 703: generating a high-density plasmas through inductive coupling, and performing ion bombardment with bias power, so that a first deposited thin film is formed in the STI and on the surface of the substrate;

step 704: stopping feeding SiH₄ and O₂, and then beginning a physical and chemical etching process with H₂ and NF₃.

In step 703, S/D is low to increase the deposition rate so that the thin film can grow from bottom of the gap without closing the opening.

Unlike embodiment 1, the etching gases in said embodiment further include NF₃, and F-containing atoms or free species will be left in the deposited thin film or in the chamber after a portion of the thin film has been etched away. This will affect adversely the thin film quality. In order to get rid of F atoms or free species left in the thin film, a step is added in the embodiment of the present invention, which is:

step 705: stopping feeding any of the reactive gases and feeding a certain amount of H₂ so as to eliminate F atoms or free species left in the thin film.

In order to achieve a better filling effect, steps 702˜705 are repeated for N cycles, i.e. a sequence of depositing-etching-passivating are performed repeated. A second deposited thin film is formed on the surface of the first deposited thin film by deposition and etching The value of S/D for forming the second deposited thin film is equal to or slightly greater than that for the first, which may be in a range of 0.05˜0.15. And the flow of H₂ is higher than that for the formation of the first deposited thin film. For example, H₂/He is 400 sccm/300 sccm for the formation of the first deposited thin film, while H₂/He increases to 700 sccm/200 sccm when forming the second deposited thin film, thereby reducing the probability of lateral re-deposition.

The process proceeds to step 706, which includes feeding SiH₄, O₂, He and fluent dilute gas H₂, and depositing a capping layer thin film. In said step, S/D may be in a range of 0.15˜0.25 by adjusting the bias power. For example, a bias power of 7000˜10000 W may be applied to a substrate wafer with a diameter of 300 mm. The flow of H₂ may be controlled as desired to maintain the opening unclosed, meanwhile material of the deposited thin film can be sputtered onto other portions thereof with He so as to improve the uniformity of the entire thin film.

It shall be noted that in this document, such terms as first and second that indicate a relationship are merely used to differentiate one entity or operation from another, but they do not necessarily require or suggest that said entities or operations have any of such actual relationships or sequence. Moreover, the terms “comprise”, “include” or any other variants thereof intend to mean non-exclusive inclusion, such that a process, method, article or device including a series of elements includes not only these elements, but also other elements that are not explicitly listed, or includes elements inherent in said process, method, article or device. Without further limitation, the elements defined by the wording “including a/one . . . ” do not exclude the presence of other such elements in the process, method, article or device including said element.

The above descriptions of the disclosed embodiments enable professionals in the art to implement or employ the present invention. Various modifications to said embodiments would be apparent to the professionals in the art. The general principles defined in this document can be implemented in other embodiments without departing from the spirit or scope of the present invention. Therefore, the present invention is not limited to the embodiments described in the document, but it should comply with the broadest scope that is consistent with the principles and novel characteristics disclosed in this document.

What is claimed is:

1. A thin film filling method, comprising:
step A: feeding reactive gases including a silicon-containing gas, an oxygen-containing gas, an inert gas and a fluent gas into a reaction chamber where a semiconductor substrate with a trench or gap is placed;
step B: forming a plasmas of low pressure and high density from the reactive gases through HDP CVD to form a first deposited thin film in the trench or gap;
step C: feeding an etching gas and the fluent gas without feeding said silicon-containing gas and oxygen-containing gas, to sputter the surface of the first deposited thin film to prevent the trench or gap from being closed;
step D: feeding said silicon-containing gas and oxygen-containing gas without feeding said etching gas, to form a plasmas of low pressure and high density, so that a second deposited thin film is formed on the surface of the sputtered first deposited thin film;
step E: feeding said etching gas and fluent gas without feeding said silicon-containing gas and oxygen-containing gas, to sputter the surface of said second deposited thin film to prevent the trench or gap from being closed;
repeating steps D˜E for N times and then proceeding to step F, wherein N is an integer greater than or equal to 1; and
step F: feeding the silicon-containing gas and oxygen-containing gas without feeding the etching gas to form a plasmas of low pressure and high density, so that a third deposited thin film, which completely fills said trench or gap, is formed on the surface of the sputtered second deposited thin film.

2. The thin film filling method according to claim 1, wherein a Sputter/Deposition ratio for the formation of the second deposited thin film is greater than or equal to that for the formation of the first deposited thin film; and a Sputter/Deposition ratio for the formation of the third deposited thin film is greater than or equal to that for the formation of the second deposited thin film.

3. The thin film filling method according to claim 2, wherein the Sputter/Deposition ratios for the formation of the first deposited thin film and the second deposited thin film fall in the range of 0.05˜0.15.

4. The thin film filling method according to claim 3, wherein the Sputter/Deposition ratio for the formation of the third deposited thin film is in the range of 0.15˜0.25.

5. The thin film filling method according to claim 1, wherein the first deposited thin film has a thickness of 30˜50% of the depth of the trench of gap.

6. The thin film filling method according to claim 1, wherein sputtering the surface of the first deposited thin film includes etching away the first depositing thin film by 5˜15% its thickness; and
sputtering the surface of the second deposited thin film includes etching away the second deposited thin film by 5˜15% its thickness.

7. The thin film filling method according to claim 1, wherein the second deposited thin film has a thickness of ⅔˜¾ of the depth of the trench or gap.

8. The thin film filling method according to claim 1, wherein the inert gas includes H₂ or a mixture of H₂ and He.

9. The thin film filling method according to claim 8, wherein the inert gas further includes Ar.

10. The thin film filling method according to claim 1, wherein the etching gas includes H₂.

11. The thin film filling method according to claim 10, wherein the etching gas further includes NF₃.

12. The thin film filling method according to claim 11, wherein step C and step E further include:
feeding a gas that can react with residual F atoms and/or free species in the thin film without feeding the etching gas and the fluent gas, so as to eliminate the residual F atoms and/or free species in the thin film.

13. The thin film filling method according to claim 12, wherein the gas that can react with residual F atoms and/or free species in the thin film includes H₂.

14. The thin film filling method according to claim 1, wherein the fluent gas includes H₂.

15. The thin film filling method according to claim 1, wherein the silicon-containing gas includes SiH₄.

16. The thin film filling method according to claim 1, wherein the oxygen-containing gas includes O₂.

17. The thin film filling method according to claim 1, wherein if the filled thin film is fluorosilicate glass, the reactive gases further include a fluorine-containing silicon-based gas; if the filled thin film is phosphorosilicate glass, the reactive gases further include a phosphoric gas; if the filled thin film is borosilicate glass, the reactive gases further include a boron-containing gas; if the filled thin film is boron-phosphorosilicate glass, the reactive gases further include a boron-containing gas and a phosphoric gas.
